(19) United States
(12) Patent Application Publication
(10) Pub. No.: US 2013/0234185 A1
(43) Pub. Date: Sep. 12, 2013

(54) DOPED SAPPHIRE AS SUBSTRATE AND LIGHT CONVERTER FOR LIGHT EMITTING DIODE

(71) Applicants: Mark S. Akselrod, Stillwater, OK (US); James Bartz, Stillwater, OK (US)

(72) Inventors: Mark S. Akselrod, Stillwater, OK (US); James Bartz, Stillwater, OK (US)

(73) Assignee: Landauer, Inc., Glenwood, IL (US)

(21) Appl. No.: 13/783,674

(22) Filed: Mar. 4, 2013

Related U.S. Application Data
(60) Provisional application No. 61/607,047, filed on Mar. 6, 2012.

(51) Int. Cl. H01L 33/50

(52) U.S. Cl. CPC H01L 33/502
USPC 257/98; 252/301.4 R

(57) ABSTRACT

Described is a material composition comprising a crystalline sapphire material doped with two or more dopants, wherein when a primary radiation comprising blue light is propagated through the crystalline material at least a portion of the primary radiation is converted into a first secondary radiation and a second secondary radiation that is emitted from the crystalline material, wherein the first secondary radiation comprises green light and the second secondary radiation comprises red light, and wherein the primary radiation, first secondary radiation and second secondary radiation when combined produce white light. Also described are LED devices employing the material composition as a light transmissive substrate.

### CROSS-REFERENCE TO RELATED APPLICATIONS

This application claims benefit of priority to U.S. Provisional Patent Application No. 61/607,047 to Akselrod, entitled, “DOPED SAPPHIRE AS SUBSTRATE AND LIGHT CONVERTER FOR LIGHT EMITTING DIODE,” filed Mar. 6, 2012 which is incorporated herein by reference in its entirety.

### BACKGROUND

1. Field of the Invention

The present invention relates to luminescent sapphire materials.

2. Related Art

It has been difficult and expensive to produce light emitting diodes (LEDs) that emit white light and that have good thermal stability.

### SUMMARY

According to a first broad aspect, the present invention provides a device comprising: a light emitting structure for emitting a primary radiation comprises blue light when the light emitting structure is driven; and a light transmissive substrate comprising a base material of Al₂O₃ doped with two or more dopants, wherein the primary radiation is blue light, wherein when the primary radiation propagates into the light transmissive substrate at least a portion of the primary radiation propagating into the light transmissive substrate is converted into a first secondary radiation and a second secondary radiation that are emitted from the light transmissive substrate, wherein the first secondary radiation comprises green light and the second secondary radiation comprises red light, wherein at least a portion of the primary radiation that is emitted from the light emitting structure is unconverted primary radiation, and wherein the unconverted primary radiation, first secondary radiation emitted from the light transmissive substrate and second secondary radiation emitted from the light transmissive substrate combine to produce white light.

According to a second broad aspect, the present invention provides a material composition comprising: a base material of Al₂O₃, two or more dopants, wherein the material composition is a crystalline material, wherein when a primary radiation comprising blue light propagates through the crystalline material at least a portion of the primary radiation is converted into a first secondary radiation and a second secondary radiation that is emitted from the crystalline material, wherein the first secondary radiation comprises green light and the second secondary radiation comprises red light, and wherein the primary radiation, first secondary radiation and second secondary radiation when combined produce white light.

### BRIEF DESCRIPTION OF THE DRAWINGS

The accompanying drawings, which are incorporated herein and constitute part of this specification, illustrate exemplary embodiments of the invention, and, together with the general description given above and the detailed description given below, serve to explain the features of the invention.

FIG. 1 is a perspective view of the light emitting diode device according to one embodiment of the present invention comprising a phosphor converting substrate.

FIG. 2 is a schematic side view of a light emitting diode device according to one embodiment of the present invention wherein the substrate is comprised as a single-crystal phosphor which absorbs only a portion of the primary radiation emitted by the light emitting structure of the light emitting diode device.

FIG. 3 is a schematic side view of a light emitting diode device according to one embodiment of the present invention wherein the substrate is comprised as a single-crystal phosphor which absorbs at least part of the primary radiation emitted by the light emitting structure of the light emitting diode device.

FIG. 4 is a schematic side view of light transmissive substrate according to one embodiment of the present invention that includes an etched patterned or engraved pattern on the surface opposite to surface used for growing light emitting structure on the light transmissive substrate.

FIG. 5 shows an optical absorption spectrum of an aluminum oxide single crystal material doped with Mg and Cr impurities (Al₂O₃:Mg,Cr) according to one embodiment of the present invention.

FIG. 6 shows excitation-emission spectrum of an Al₂O₃:Mg,Cr material according to one embodiment of the present invention.

FIG. 7 shows an emission spectrum of an Al₂O₃:Mg,Cr material according to one embodiment of the present invention under blue (440 nm) excitation.

FIG. 8 shows performance of an Al₂O₃:Mg,Cr material according to one embodiment of the present invention at elevated temperatures.

### DETAILED DESCRIPTION OF THE PREFERRED EMBODIMENTS

### Definitions

Where the definition of terms departs from the commonly used meaning of the term, applicant intends to utilize the definitions provided below, unless specifically indicated.

For purposes of the present invention, directional terms such as “top”, “bottom”, “upper”, “lower”, “above”, “below”, “left”, “right”, “horizontal”, “vertical”, “upward”, “downward”, etc., are merely used for convenience in describing the various embodiments of the present invention.

For purposes of the present invention, the term “absorption band in the region of” or “emission band in the region of” refers to an absorption or emission band having a peak in the appropriate region. Sometimes the region may be a particular wavelength and sometimes the region may include a range of wavelengths indicating a possible shift in a band peak position.

For purposes of the present invention, the term “base material” refers to the material that makes up the majority of a doped material. For example, Al₂O₃ would be the base material in Al₂O₃ doped with Mg and Cr.

For purposes of the present invention, the term “blue light” refers to a spectral composition of light that human eye and brain see as blue. Blue light includes light having a wavelength in the range from 450 to 495 nm.

For purposes of the present invention, the term “charge-compensated” refers to a defect in a crystal lattice that electro-statically compensates the electrical charge of another defect. For example, in one embodiment of the present invention, Mg, and Cr impurities may be used to charge-compensate one oxygen vacancy defect, two oxygen vacancy defects, a cluster of these defects, etc. comprising F₂²⁺(2Mg)-centers.

For purposes of the present invention, the term “color center” refers to structural defects in the luminescent materials that are able to absorb and/or emit light at particular wavelengths. This definition of “color center” includes the conventional meaning of the term “color center”, i.e., a point defect in a crystal lattice that gives rise to an optical absorption in a crystal and upon light excitation produces a photon of luminescence. A color center, an impurity or an intrinsic defect in a crystalline material creates an unstable species. An electron localized on this unstable species or defect performs quantum transition to an excited state by absorbing a photon of light and performs quantum transition back to a ground state by emitting a photon of luminescence. In one embodiment of the present invention, color centers are present in a concentration of about 10¹³ cm⁻³ to 10¹⁹ cm⁻³.

For purposes of the present invention, the term “crystalline material” refers to the conventional meaning of the term “crystalline material”, i.e., any material that has orderly or periodic arrangement of atoms in its structure.

For purposes of the present invention, the term “Czochralski method” refers to the well-known Czochralski crystal growth technique described in such places as: Crystal Growth in Science and Technology, edited by H. Arendt and J. Hulliger, New York: Plenum Press, 1989; Y. A. Tatarchenko, Shaped Crystal Growth, Dordrecht/Boston/London: Kluwer Academic Publishers, 1993; the entire contents and disclosures of which are hereby incorporated by reference. The Czochralski method involves a formation of a single crystalline body by immersing a single crystal seed into a melt pool and then pulling the single crystal seed out of the melt with simultaneous rotation.

For purposes of the present invention, the term “defect” refers to the conventional meaning of the term “defect” with respect to the lattice of a crystal, i.e., a vacancy, interstitial, impurity atom or any other imperfection in a lattice of a crystal.

For purposes of the present invention, the term “downconversion” refers to the process in luminescent material when the absorption of light of primary radiation results in emission of light with lower energy photons of secondary radiation.

For purposes of the present invention, the term “drive” refers to supplying a device with current that activates the device. For example, a biasing current may be used to drive an LED to cause the LED to emit light.

For purposes of the present invention, the term “efficient deep trap” refers to a deep trap which is capable of trapping electrons or holes and which has a sufficient capture cross-section.

For purposes of the present invention, the term “electron trap” refers to a structural defect in a crystal lattice able to create a localized electronic state and capable of capturing free electrons from a conduction band of the crystalline material.

For purposes of the present invention, the term “fluorescence yield” refers to the parameter determined as a ratio of the number of photons emitted by a luminescent material to the number of photons absorbed by this fluorescent material.

For purposes of the present invention, the term “F-type center” refers to any one of the following centers: F-center, F⁺-center, F₂⁺-center, F₂⁺⁺-center, F₂⁺(2Mg)-center, F₂⁺⁺(2Mg)-center, etc.

For purposes of the present invention, the term “green light” refers to a spectral composition of light that human eye and brain see as green. Green light includes light having a wavelength in the range from 495 to 570 nm.

For purposes of the present invention, the term “highly reducing atmosphere” refers to the atmosphere with a low partial pressure of oxygen.

For purposes of the present invention, the term “hole trap” refers to a structural defect in a crystal lattice able to create a localized electronic state and capable of capturing free holes from a conduction band of the crystalline material.

For purposes of the present invention, the term “light transmissive substrate” refers to a substrate through which one or more wavelengths of visible light may be transmitted.

For purposes of the present invention, the term “low partial pressure of oxygen” refers to the partial pressure of oxygen in the mixture of gases that is below 10⁻³ atm.

For purposes of the present invention, the term “luminescence lifetime” or “fluorescence lifetime” refers to a time constant of an exponential decay of luminescence or fluorescence.

For purposes of the present invention, the term “luminescence” refers to the emission of light by a substance not resulting from heat.

For purposes of the present invention, the term “operating temperature range” refers to the temperature range in which a luminescent material will emit light under excitation.

For purposes of the present invention, the term “oxygen vacancy defect” refers to a defect caused by an oxygen vacancy in a lattice of a crystalline material. An oxygen vacancy defect may be a single oxygen vacancy defect, a double oxygen defect, a triple oxygen vacancy defect, or a more than triple oxygen vacancy defect. An oxygen vacancy defect may be associated with one or more impurity atoms or may be associated with an interstitial intrinsic defect such as misplaced interstitial oxygen atoms. Occupancy of an oxygen vacancy by two electrons gives rise to a neutral F-center, whereas occupancy of any oxygen vacancy by one electron forms an F⁺-center. An F⁺-center has a positive charge, with respect to the lattice. A cluster of oxygen vacancy defects formed by double oxygen vacancies is referred to as an F₂-type center. A cluster of oxygen vacancy defects formed by two F⁺-centers and charge-compensated by two Mg-impurity atoms is referred to as a F₂²⁺(2Mg)-center.

For purposes of the present invention, the term “parts per million (ppm)” when referring to a compound that is part of a mixture prior to crystallization refers to the weight ratio of that compound to the weight of the mixture as a whole. For purposes of the present invention, the term “parts per million (ppm)” when referring to an element present in a mixture prior to crystallization refers to the weight ratio of the compound or the molecule containing that element to the weight of the mixture as a whole. For example, if Mg is present in a mixture prior to crystallization at a concentration of 500 ppm and Mg is present in the mixture as MgO, MgO is present at a concentration of 500 ppm of the total weight of the mixture. For purposes of the present invention, the term “parts per million (ppm)” when referring to an element present in a crystal refers to the weight ratio of the element to weight of the crystal as a whole. For example, if Mg is present in a crystal at 27 ppm, this indicates that the element Mg is present in the crystal at a concentration of 27 ppm of the total weight of the crystal.

For purposes of the present invention, the term “red light” refers to a spectral composition of light that human eye and brain see as red. Red light includes light having a wavelength in the range from 620 to 750 nm.

For purposes of the present invention, the term “reflective electrode” refers to a structure that functions both as reflective surface and a current conductor for an LED device.

For purposes of the present invention, the term “spectral band” is intended to denote a band of potentially many light wavelengths.

For purposes of the present invention, the term “substantially insensitive to room light” refers to a crystalline material that does not change significantly its coloration or concentration of electrons on traps (concentration of unstable species) under ambient light conditions.

For purposes of the present invention, the term “thermal quenching” refers to the process in luminescent material in which the intensity of luminescent light emission decreases with the increase of luminescent material temperature.

For purposes of the present invention, the term “unconverted radiation” refers radiation that is not converted to another form of radiation. For example, primary radiation that does not pass through a light transmissive substrate is unconverted radiation and may be referred to as unconverted primary radiation. Also, primary radiation that passes through a light transmissive substrate and is not converted into another form of radiation is also unconverted radiation and may be referred to as unconverted primary radiation.

For purposes of the present invention, the term “wavelength” is intended to denote the wavelength of the peak intensity of a spectral band.

For purposes of the present invention, the term “white light” refers to a spectral composition of light that human eye and brain see as white. In technical terms according the CIE-1931 standard it is defined as a light composition corresponding to the “E” point in the XYZ chromaticity diagram. One of the simplest examples of “E” or “Equal Energy” spectrum is when spectral power distribution is flat, giving the same power per unit wavelength at any wavelength. For common human eye perception white light can be produced by combining and controlling the intensity of three primary colors (RGB—red, blue and green).

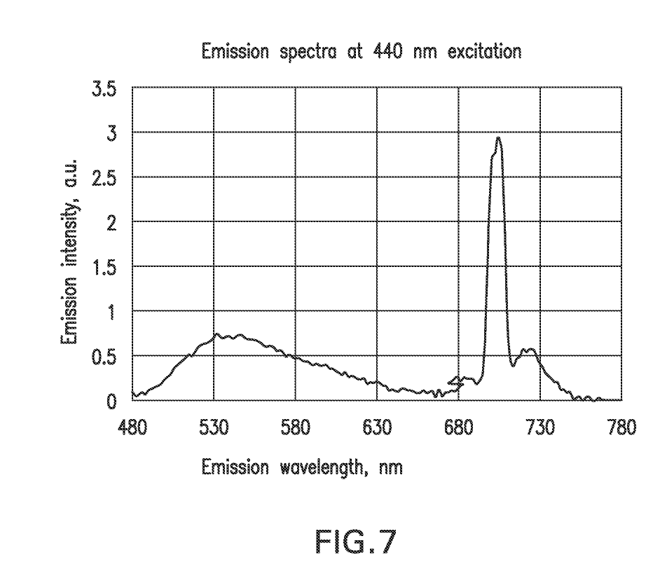

For purposes of the present invention, the term “wide emission band” refers to an emission band that has full width at half maximum bigger than 0.1 eV and is a result of strong electron-phonon interaction. One example of a wide emission band is the wide emission band around 520 nm in FIG. 7.

### DESCRIPTION

In one embodiment, the present invention provides a doped sapphire single crystal both as an LED substrate for high-brightness GaN-based light emitting diode (LED) devices and as a blue light converter capable of generating white light of a desired spectral composition.

In one embodiment, the present invention provides a new material composition (aluminum oxide doped with magnesium and chromium) in the form a single crystal sapphire that may be used as a light converter (phosphor).

Currently sapphire wafers are widely used as substrates for GaN-based high brightness light emitting devices. One advantage of using a c-plane sapphire as a substrate material is relatively good lattice match with GaN crystal structures. Currently, for general lighting applications LEDs employ GaN-based quantum well structures emitting blue light and use light converters (phosphors) made of rare earth (RE) oxides to convert blue light into white (wide spectral composition) light.

RE oxides are powders that are expensive, have limited conversion efficiency and exhibit thermal quenching at elevated operating temperatures. RE oxides are often used in LEDs as a mixture with organic binders (epoxies) that limit the operating temperature of an LED.

In one embodiment, the present invention uses sapphire wafers containing specially added impurities as both a substrate for metal oxide chemical vapor deposition (MOCVD) growth of GaN-based LED devices and as a light converter with high conversion efficiency and capable of operating at elevated temperature (up to 300° C.).

Hydride vapor phase epitaxy (HVPE), is another applicable technique to manufacture GaN layers on top of the sapphire substrate. HVPE is generally much faster than the standard MOCVD technique in widespread use today and may further cut the cost of solid-state lighting.

U.S. Pat. No. 6,630,691 to Mueller-March et al., the entire contents and disclosure of which are incorporated by reference, describes the utilization of single crystal media based on doped Yttrium Aluminum Garnet (YAG) as both a substrate and as a blue to yellow light converter with the intention to improve the performance of white LED devices. One disadvantage of YAG crystal as a substrate material is significant lattice mismatch with GaN epitaxial layers and the fact that YAG crystals and wafers are extremely expensive due to the high cost of raw material (yttrium oxide) and very slow growth rate in commercial production.

In contrast, in one embodiment, the present invention use sapphire crystals intentionally doped with impurities. In one embodiment of the present invention, the impurities include magnesium and chromium to produce sapphire crystal having optical absorption bands in the blue region of the spectrum and able efficiently absorb blue light and emit green and red light. Quantum efficiency of this photoconversion process for such a material is high. Coefficient of optical absorption of different absorption bands and Intensity of fluorescence in green and red part of the spectrum are tuned to produce white light of desired “color temperature.”

In addition to impurities, intrinsic defects may be used to create so called color centers (defects absorbing and emitting light). These defects may be in the form of single vacancies, double vacancies, and/or aggregate defects containing both impurities and vacancy defects. These defects and color centers are produced in sapphire during crystal growth and high temperature annealing.

In one embodiment, the present invention uses a doped sapphire (Al₂O₃:Mg,Cr) as a substrate to grow GaN-based devices using a MOCVD process or one of its modifications. Sapphire is already widely used commercially as a LED substrate material and is both a cost efficient and technically efficient material. Using sapphire as both a substrate and a light converter in various embodiment of the present invention may provide several advantages over existing substrate/light converter combinations.

In one embodiment of the present invention, in addition to or instead of using Mg and Cr as dopants, other dopants such as Fe, V and other transition metals may be used to obtain the desired optical absorption and luminescence.

In one embodiment, the doped sapphire may have surface patterning. Such surface patterning may be formed, for example, by using etching technique, MOCVD employing a mask, etc. Such surface patterning may prevent or reduce total internal light reflection and to achieve higher light extraction efficiency from the LED device. An additional advantage of doped sapphire patterning is an increase in the length of the light path due to multiple reflections within the sapphire substrate that produces increases in light absorption efficiency and photoconversion. A longer light path length may allow for the use of lower concentrations of impurities and improved crystal growth conditions.

In one embodiment of the present invention, sapphire crystals doped with Mg and Cr impurities may be grown using the Czochralski crystal growth technique.

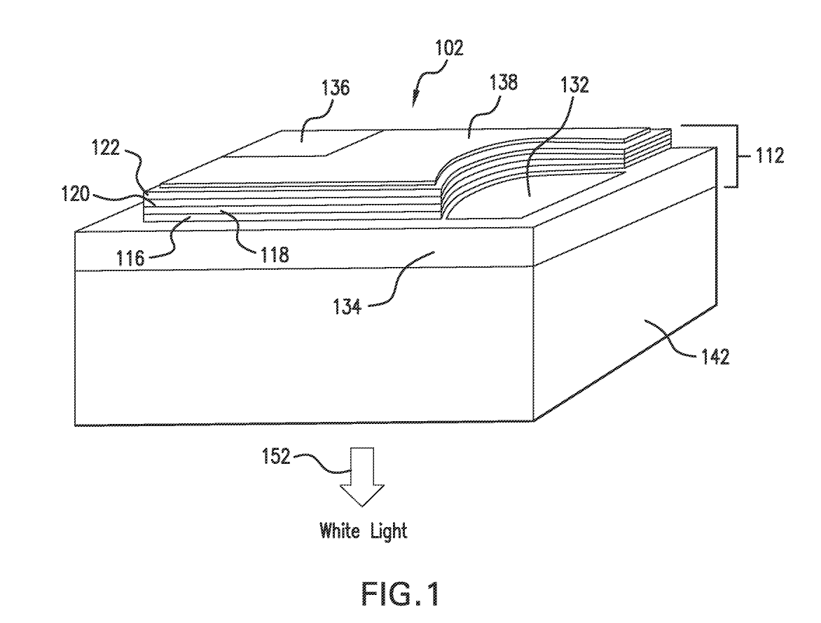

FIG. 1 is a perspective view of a light emitting diode (LED) device 102 that is suitable for incorporating a phosphor-converting substrate of the present invention. However, it should be noted that the LED of the present invention is not limited to any particular type of LED. Those skilled in the art will understand that a variety of LEDs are available on the market that are suitable for use with the present invention.

LED device 102 includes a light emitting structure 112, which comprises an n-GaN layer 116, a single quantum well (SQW) or multiple quantum well (MQW) GaInN layer 118, a p-AlGaN layer 120 and a p-GaN layer 122. Light emitting structure 112 also comprises an n-electrode bond pad 132, an n-electrode 134, a p-electrode bond pad 136 and a p-electrode 138. N-electrode 134 is comprised of GaN and the p-electrode 138 is either transmissive or reflective, as discussed below in more detail. P-electrode 138 is reflective and the light emitted by light emitting structure 112 propagates downward and into a light transmission substrate 142. N-electrode bond pad 132 and p-electrode bond pad 136, when connected to a power supply (not shown), provide the biasing current for causing LED device 102 to emit white light 152. Light emitting structure 112 is disposed on light transmission substrate 142, which is a single crystal phosphor.

It should be noted that the materials used for creating an LED device of the present invention, such as LED device 102, are not limited to the materials discussed above with reference to FIG. 1. Those skilled in the art will understand that a light emitting diode of the present invention may be comprised of various types of materials. As stated above, the light emitting diode is not limited to any particular type of light emitting diode. Those skilled in the art will understand that various light emitting diodes are known that are suitable for this purpose. For example, single-quantum-well and multiple-quantum-well light emitting diodes are suitable for this purpose.

In one embodiment of the present invention, a light emitting structure that generates the primary blue emission may be grown epitaxially on the single crystal phosphor substrate. In one embodiment, the substrate is a single crystal Al₂O₃ compound, such as a sapphire, doped with two or more metal ions. In one embodiment, the substrate is Al₂O₃ doped with Mg and Cr. Sapphires have desirable thermal, mechanical and crystalline structure properties that make sapphires particularly useful in LED devices.

As is understood in the art, the substrate utilized in an LED device should closely match the crystalline structure of the n-electrode. In one embodiment of the present invention the n-electrode of the LED device is comprised of GaN. A single crystal Al₂O₃ compound, even containing two or more dopants, has a crystalline structure that sufficiently matches the crystalline structure of GaN such that the single crystal Al₂O₃ compound is suitable for use as the substrate of an LED device. In addition, doping Al₂O₃ with Mg and Cr produces both a green light-emitting phosphor and a red light-emitting phosphor, so that a single crystal Al₂O₃ compound doped with Mg and Cr may serve the dual purpose of providing all of the necessary functions of an LED device, providing a substrate for blue light emitting structure growth and phosphor function by downconversion of the primary blue light into green and red emission both of which in combination with the residual primary blue light produce light that human eye sees as white.

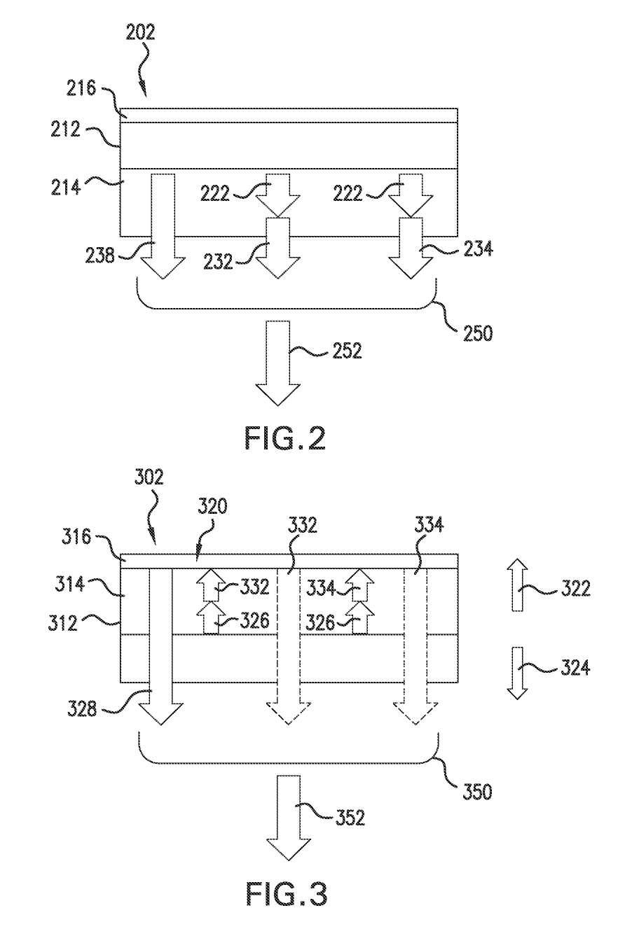

FIG. 2 shows an LED device 202 according to one embodiment of the present invention that includes a light emitting structure 212 sandwiched between and in contact with a light transmissive substrate 214 and a reflective electrode 216. Light emitting structure 212 emits primary radiation 222. Light transmissive substrate 214 luminesces secondary radiation 232 and secondary radiation 234 in response to receiving primary radiation 222 generated by the light emitting structure 212 of LED device 202. A portion of primary radiation generated by light emitting structure 212, i.e., unconverted primary radiation 238, passes through the light transmissive substrate 214 and remains unconverted. Unconverted primary radiation 238 then combines, as indicated by bracket 250, with secondary radiation 232 and secondary radiation 234 to produce white light 252. For ease of illustration, some components of the light emitting structure 212 are not shown in FIG. 2.

Some of the primary radiation emitted by the light emitting structure may impinge on the reflective electrode, which will reflect the primary radiation back through light emitting structure and through the light transmissive substrate. This reflected primary radiation may be converted to the two types of secondary radiation shown in FIG. 2 or be emitted as unconverted radiation.

Utilizing a reflective electrode in the LED device of FIG. 2 improves the efficiency of the LED by ensuring that the amount of primary light entering the light transmissive substrate is maximized.

FIG. 3 is a side view of an LED device 302 according to one embodiment of the present invention. LED device 302 includes a light emitting structure 312, a light transmissive substrate 314 and a reflective surface 316. Reflective surface 316 is disposed on a surface 320 of light transmissive substrate 314 opposite light emitting structure 312. Light emitting structure 312 emits primary radiation in two opposite directions, the direction shown by arrow 322 and the direction shown by arrow 324. Primary radiation emitted in the direction shown by arrow 322 is shown in FIG. 3 as primary radiation 326. Primary radiation in the direction show by arrow 324 is shown as primary radiation 328. Primary radiation 326 emitted by light emitting structure 312 propagates into light transmissive substrate 314. Substantially all of primary radiation 326 is converted into secondary radiation 332 and secondary radiation 334 by light transmissive substrate 314. Secondary radiation 332 and secondary radiation 334 is reflected by reflective surface 316, in a direction, indicated by arrow 324, away from reflective surface 316 toward light emitting structure 312. Reflected secondary radiation 332 and secondary radiation 334, shown as dashed arrows, passes through light emitting structure 312 and combines with primary radiation 328, as indicated by bracket 350 to produce white light 352. Primary radiation 328 is unconverted primary radiation.

In one embodiment of the present invention in which the light transmissive substrate, such as the light transmissive substrate shown in FIG. 1, 2 or 3, comprises Al₂O₃ doped with Mg and Cr, the primary radiation may be blue light the secondary radiations may be green light and red light, respectively, may be precisely controlled so that the fraction of primary radiation that passes through the light transmissive substrate without being converted is predictable and controllable. The characteristics of the light transmissive substrate may be precisely controlled by precisely adjusting the doping level of the light transmissive substrate. By precisely controlling the characteristics of the light transmissive substrate, the fraction of primary light that is converted by the substrate into red and green light may be predictable and controllable. By precisely controlling this fraction, variations in the quality of the white light produced by the LED can be minimized or eliminated.

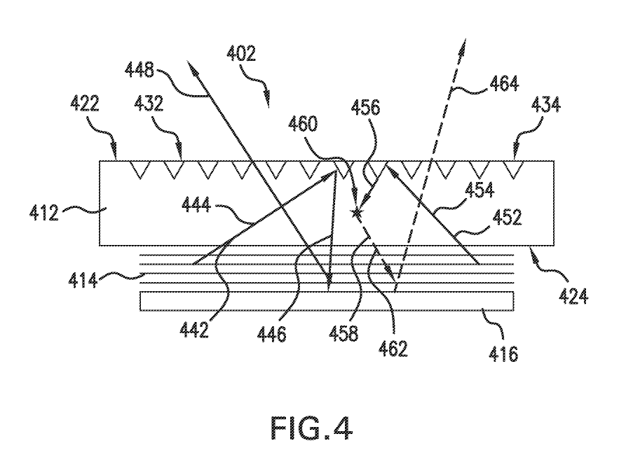

FIG. 4 illustrates an embodiment of the present invention in which the light transmissive substrate includes an etched patterned or engraved pattern on the surface opposite to surface used for growing light emitting structure on the light transmissive substrate.

FIG. 4 shows an LED device 402 including a patterned light transmissive substrate 412, a light emitting structure 414 and a reflective layer 416. Patterned light transmissive substrate 412 includes a patterned surface 422 and a surface 424 opposite patterned surface 422. Surface 424 is in contact with light emitting structure 414. Patterned surface 422 includes a pattern 432 formed by etched or engraved recesses 434. Blue light primary radiation 442 emitted by light emitting structure 414 enters patterned light transmissive substrate 412 as shown by arrow 444, is reflected by pattern 432 back through patterned light transmissive substrate 412 and light emitting structure 414 as shown by arrow 446, is reflected by reflective layer 416 through light emitting structure 414 and patterned light transmissive substrate 412 and then is emitted from LED device 402 as shown by arrow 448. As can be seen, the reflection of blue light primary radiation 442 by pattern 432 increases the light path, i.e., the path shown by arrows 444, 446 and 448, of blue light primary radiation 442. Blue light primary radiation 452 emitted by light emitting structure 414 enters patterned light transmissive substrate 412 as shown by arrow 454 and is reflected by pattern 432 back into patterned light transmissive substrate 412 as shown by arrow 456 where blue light primary radiation 452 is downconverted to secondary radiation 456 as indicated by star 460. Secondary radiation 458 continues to travel through patterned light transmissive substrate 412 and light emitting structure 414 as shown by arrow 462, and is reflected by reflective layer 416 through light emitting structure 414 and patterned light transmissive substrate 412 and then is emitted from LED device 402 as shown by arrow 464. As can be seen, the reflection of blue light primary radiation 452 by pattern 432 increases the light path, i.e., the path shown by arrow 454 and 456, of blue light primary radiation 442 allows for primary radiation that would otherwise be emitted as primary radiation to be downconverted to secondary radiation.

Although for simplicity of illustration, only a single reflection of primary radiation in show in FIG. 4, the primary radiation may be reflected two or more times before being emitted from the LED device as primary radiation or downconverted to secondary radiation.

An etched or engraved pattern on a surface of the light transmissive substrate may be used to cause multiple reflections of primary radiation within the light transmissive substrate, to increase the path length for absorption of primary radiation and to increase the efficiency of light downconversion. Additionally, such a pattern may increase the light extraction efficiency of primary and secondary radiations.

For simplicity of illustration only a simple pattern is shown in FIG. 4. However, a patterned substrate may have any type of pattern formed on the surface of the substrate.

The reflective layer of FIG. 4 may be a reflective surface or a reflective electrode. Although the light emitting structure of FIG. 4 is shown as a multiple quantum well structure, the light emitting structure may be a single quantum well structure in the embodiment of the present invention illustrated in FIG. 4.

In one embodiment of the present invention the emission of secondary radiation from the crystalline material of the substrate is stable during operation of an LED device at temperatures greater than 20° C. In one embodiment, the crystalline material used as a substrate has an operating temperature range from −100° C. to +400° C.

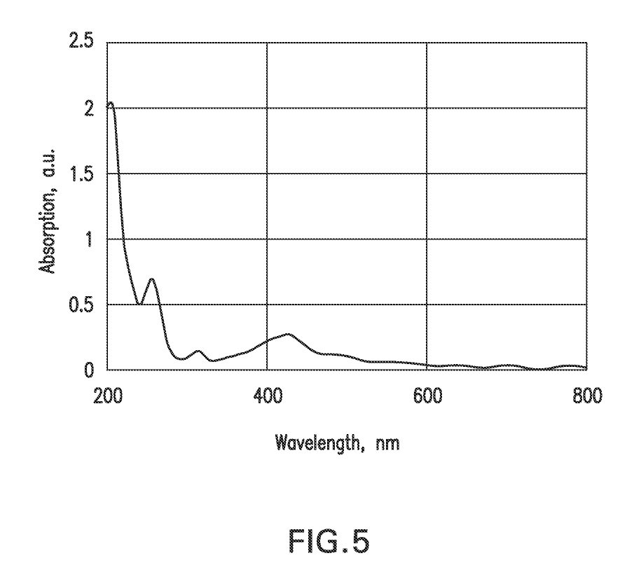

Sapphire crystals doped with Mg and Cr impurities were grown using the Czochralski crystal growth technique. Thin wafers of these crystals were cut and polished. Quantitative optical measurements were performed to characterize optical absorption and luminescence of the crystals doped with different concentration of suggested impurities. FIG. 5 shows and optical absorption spectrum of one of these crystals.

FIG. 5 depicts optical absorption spectrum of the luminescent Al₂O₃ crystal doped with Mg and Cr and having plurality of single and double oxygen vacancies. The presence of these defects and corresponding color centers is evidenced by spectral absorption bands peaked at 205, 255, 360, 405, 435, 560 and 620 nm. Spectral absorption bands peaked at 405 and 435 nm is utilized in one of the embodiment of the present invention to for absorption of primary radiation (blue) light and downconverting the primary radiation into a first secondary radiation (green emission at 520 nm emission band) and a second secondary radiation (red emission band near 700 nm). Although for simplicity of explanation in the embodiments described above the term “first secondary radiation” refers to a green emission and the term “second secondary radiation” refers to a red emission, the terms “first secondary radiation” and “second secondary radiation” may refer to any color of emission due to luminescence.

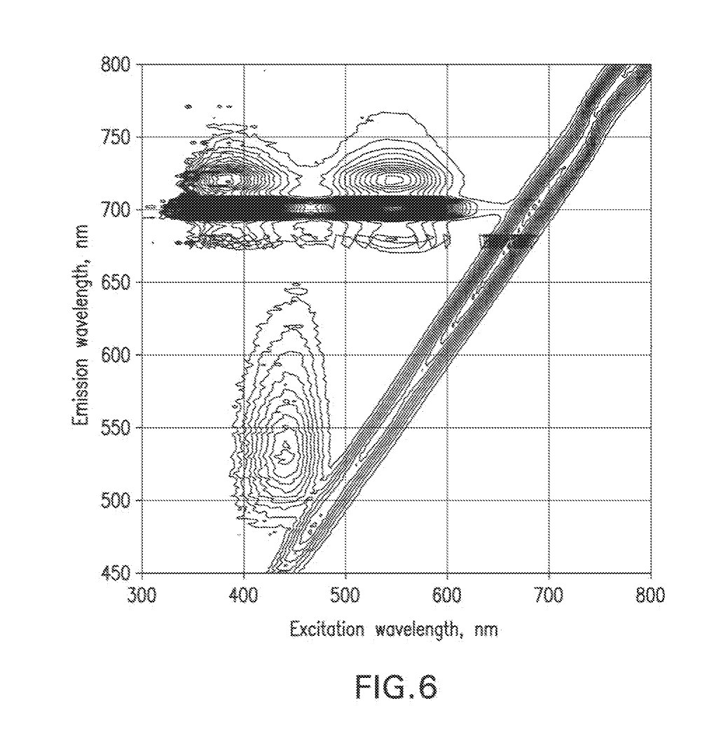

In one embodiment of the present invention the material for a light transmissive substrate comprising of Al₂O₃ doped with Mg and Cr and having plurality of single and double oxygen vacancy defects was grown in a such way that plurality of absorptive and luminescent color centers were produced as illustrated by the absorption spectrum in FIG. 5 and the excitation-emission spectrum in FIG. 6.

FIG. 6 is the excitation-emission spectrum of the Al₂O₃:Mg,Cr material claimed in the present invention, where the vertical axis of the graph refers to the wavelength of the excitation and absorption light and horizontal axis refers to the wavelength of the emitted luminescent light. The emission spectral bands are depicted in FIG. 6 as peaks on the contour plot and referred in the present invention as the first and second secondary radiations.

FIG. 7 depicts the emission spectrum of one of the tested crystals under blue (440 nm) excitation as an illustration of the downcoversion process according to the present invention indicating two or more spectral bands in green and red part of the visible spectral range.

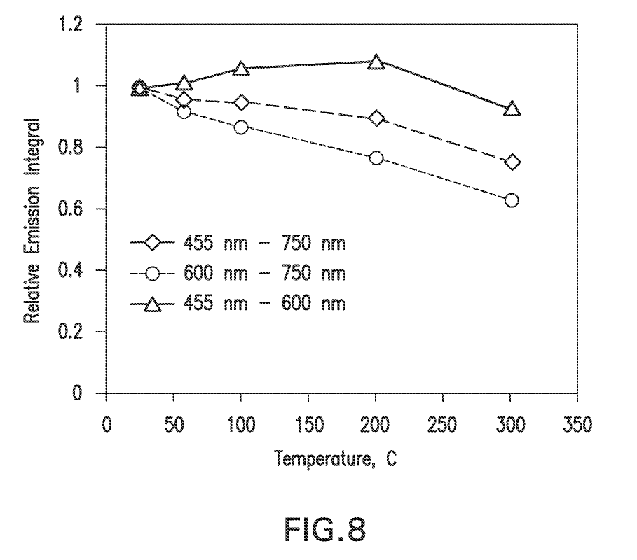

FIG. 8 illustrates the performance of the luminescent material at elevated temperatures, where spectral bands of the first secondary radiation (455-600 nm) and the second secondary radiations (600-750 nm) show only small decrease in light output within the temperature range from room temperature to 300 C.

In yet another embodiment of the present invention it is claimed high thermal stability of luminescence emission at elevated temperature of material operation.

It should be noted that the primary radiation may comprise light having more than one wavelength. Similarly, the light emitted in response to excitation by the primary light may comprise light of more than one wavelength. For example, the green and red secondary radiation emitted by the substrate may correspond to a plurality of wavelengths making up a spectral band. Wavelengths of both of these spectral bands may then combine with the unconverted primary light to produce white light. Therefore, although individual colors and wavelengths are discussed herein for purposes of explaining the concepts of the present invention, it will be understood that the excitation and emission being discussed herein may result in a plurality of wavelengths, or a spectral band, being emitted. Light with particular wavelengths within spectral bands may then combine to produce white light.

All documents, patents, journal articles and other materials cited in the present application are incorporated herein by reference.

While the present invention has been disclosed with references to certain embodiments, numerous modification, alterations, and changes to the described embodiments are possible without departing from the sphere and scope of the present invention, as defined in the appended claims. Accordingly, it is intended that the present invention not be limited to the described embodiments, but that it has the full scope defined by the language of the following claims, and equivalents thereof.

What is claimed is:

1. A device comprising:
a light emitting structure for emitting a primary radiation comprises blue light when the light emitting structure is driven; and
a light transmissive substrate comprising a base material of Al₂O₃ doped with two or more dopants,
wherein the primary radiation is blue light,
wherein when the primary radiation propagates into the light transmissive substrate at least a portion of the primary radiation propagating into the light transmissive substrate is converted into a first secondary radiation and a second secondary radiation that are emitted from the light transmissive substrate,
wherein the first secondary radiation comprises green light and the second secondary radiation comprises red light,
wherein at least a portion of the primary radiation that is emitted from the light emitting structure is unconverted primary radiation, and
wherein the unconverted primary radiation, first secondary radiation emitted from the light transmissive substrate and second secondary radiation emitted from the light transmissive substrate combine to produce white light.

2. The device of claim 1, wherein the device comprises:
a reflective surface,
wherein the light transmissive substrate is sandwiched between and in contact with the light emitting structure and the reflective surface,
wherein the unconverted primary radiation comprises primary radiation emitted by the light emitting structure in a direction away from the light transmissive substrate,
wherein the reflective surface reflects the first secondary radiation and the second secondary radiation through the light transmissive substrate and the light emitting structure to thereby produce reflected first secondary radiation and reflected second secondary radiation, and
wherein the reflected first secondary radiation, the reflected second secondary radiation and the unconverted primary radiation combine to form white light.

3. The device of claim 1, wherein the device comprises:
a reflective electrode disposed on a first surface of the light emitting structure,
wherein any primary radiation emitted by the light emitting structure, first secondary radiation and the second secondary radiation that impinge on the reflective electrode are reflected back by the reflective electrode toward the light emitting structure and light transmissive substrate.

4. The device of claim 1, wherein the light transmissive substrate includes a patterned surface, wherein the light emitting structure is located on a surface of the light transmissive substrate opposite the patterned surface, wherein the patterned surface comprises a pattern for causing multiple reflections of the primary radiation within the light transmissive substrate, wherein the pattern increases a path length of the primary radiation to thereby increase absorption of the primary radiation by the light transmissive substrate and/or to increase downconversion of the primary radiation and/or increase light extraction efficiency of the primary radiation and/or the first secondary radiation and/or the second secondary radiation.

5. The device of claim 1, wherein the two or more dopants comprise magnesium and chromium.

6. A material composition comprising:
a base material of Al₂O₃,
two or more dopants,
wherein the material composition is a crystalline material,
wherein when a primary radiation comprising blue light propagates through the crystalline material at least a portion of the primary radiation is converted into a first secondary radiation and a second secondary radiation that is emitted from the crystalline material,
wherein the first secondary radiation comprises green light and the second secondary radiation comprises red light, and
wherein the primary radiation, first secondary radiation and second secondary radiation when combined produce white light.

7. The material composition of claim 6, wherein the two or more dopants comprise magnesium and chromium.

8. The material composition of claim 6, where the material contains plurality of single and double oxygen vacancies and when combined with dopants the vacancies produce aggregate defects that absorb the primary radiation and emit the first secondary radiation and the second secondary radiation.

9. The material composition of claim 6, wherein emission of the first secondary radiation and the second secondary radiation from the crystalline material is stable during operation at temperatures greater than 20° C.

10. The material composition of claim 9, wherein the crystalline material has operating temperature range from −100° C. to +400° C.
